(19) United States
(12) Patent Application Publication
(10) Pub. No.: US 2009/0009218 A1
(43) Pub. Date: Jan. 8, 2009

(54) Literal Gate Using Resonant Tunneling Diodes

(75) Inventors: Kwang-Seok Seo, Seoul (KR); Hyung-Tae Kim, Seoul (KR)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: SEOUL NATIONAL UNIVERSITY INDUSTRY FOUNDATION, Seoul (KR)

(21) Appl. No.: 12/136,250

(22) Filed: Jun. 10, 2008

(30) Foreign Application Priority Data
Jul. 5, 2007 (KR) 10-2007-0067426

(51) Int. Cl. H03K 19/10; H03K 17/58

(52) U.S. Cl. 326/134; 327/499

(57) ABSTRACT

The present invention relates to a literal gate using resonant tunneling diodes; and, more particularly, to a literal gate using only resonant tunneling diodes (RTDs).

The present invention has an advantage in that it can provide a literal gate using resonant tunneling diodes, using fewer elements than a convention literal gate, utmost utilizing the input-output characteristics of an RTD, and reducing fabricating costs and improving a yield.

### BACKGROUND OF THE INVENTION

1. Field of the Invention

The present invention relates to a literal gate using resonant tunneling diodes; and, more particularly, to a literal gate using only resonant tunneling diodes (RTDs).

2. Background of the Related Art

Any discussion of the prior art throughout the specification should in no way be considered as an admission that such prior art is widely known or forms part of common general knowledge in this field.

A literal gate is the logic having an output in a high state only for a certain input area. Since such multiple-valued logic (MVL) is able to process a mass of data all at once compared to a binary logic, it can reduce complexity of circuits such as ultra large scale integration (ULSI) circuit or a very large scale integration (VLSI) circuit and solve wiring problems, which has been getting worse.

A circuit configuration of a conventional literal gate is shown in FIG. 1. the conventional literal gate comprises the resonant tunneling diodes (RTDs) A, B, and X and the transistors T1 and T2 for current modulation. In this configuration, the RTDs and the transistors have to be optimized at the same time in order to optimize performance of the literal gate, and the conventional literal gate needs the processes more complicated than a circuit using only transistors does. In addition to these problems, in the conventional literal gate, the transistor countervails the advantages of RTDs since the transistors have bigger parasitic capacitance and occupy bigger chip area than RTDs.

### SUMMARY OF THE INVENTION

Accordingly, the present invention is directed to a literal gate using resonant tunneling diodes that substantially obviates one or more problems due to limitations and disadvantages of the related art.

It is an object of the present invention to provide a literal gate using resonant tunneling diodes, utmost utilizing the input-output characteristics of an RTD.

Another object of the present invention is to provide a literal gate using resonant tunneling diodes having fewer active elements than a conventional literal gate.

Still another object of the present invention is to provide a literal gate using resonant tunneling diodes, capable of miniaturizing the size of a circuit compared to a conventional literal gate.

Still another object of the present invention is to provide a literal gate using resonant tunneling diodes, which is embodied with active elements of only one kind, thus can simplify the fabricating process and improve the yield.

To accomplish the above objects, according to the present invention, there is provided a literal gate determining an output value of the literal gate according to an input value of an output terminal which is determined by an output value from an input terminal, the literal gate using resonant tunneling diodes, wherein the input terminal includes a resistance and a resonant tunneling diode (RTD) which are connected in series, to determine the input value.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1 is a circuit configuration of a conventional literal gate;

FIG. 2 shows a graph of I-V characteristics of an RTD;

FIG. 3 depicts a circuit configuration of a literal gate according to one embodiment of the present invention;

FIG. 4a and FIG. 4b show graphs of output characteristics of an output terminal according to the present invention;

FIG. 5 shows graphs of output characteristics of an input terminal according to the present invention; and

FIG. 6 is a graph showing output values of a literal gate according to the present invention.

### DETAILED DESCRIPTION OF THE PREFERRED EMBODIMENT

The present invention will now be described more fully with reference to the accompanying drawings, in which exemplary embodiments of the invention are shown. The invention may, however, be embodied in many different forms and should not be construed as being limited to the embodiments set force herein, rather, these embodiments are provided so that this disclosure will be thorough and complete, and will fully convey the concept of the invention to those skilled in the art.

FIG. 2 is a graph showing I-V characteristics with respect to an RTD. Referring to FIG. 2, if 0<V<V_{P}, the RTD shows positive differential resistance (PDR) 1, i.e., in this region, current increases with an increment of voltage. If V_{P}<V<V_{V}, the RTD shows negative differential resistance (NDR). Next, for V>V_{V}, the RTD shows PDR2, where current increases according to increment of voltage.

At this time, the current value when the voltage is V_{P} is expressed as a peak current (I_{P}). In other words, the I_{P} is the current value when current stops increasing and starts decreasing.

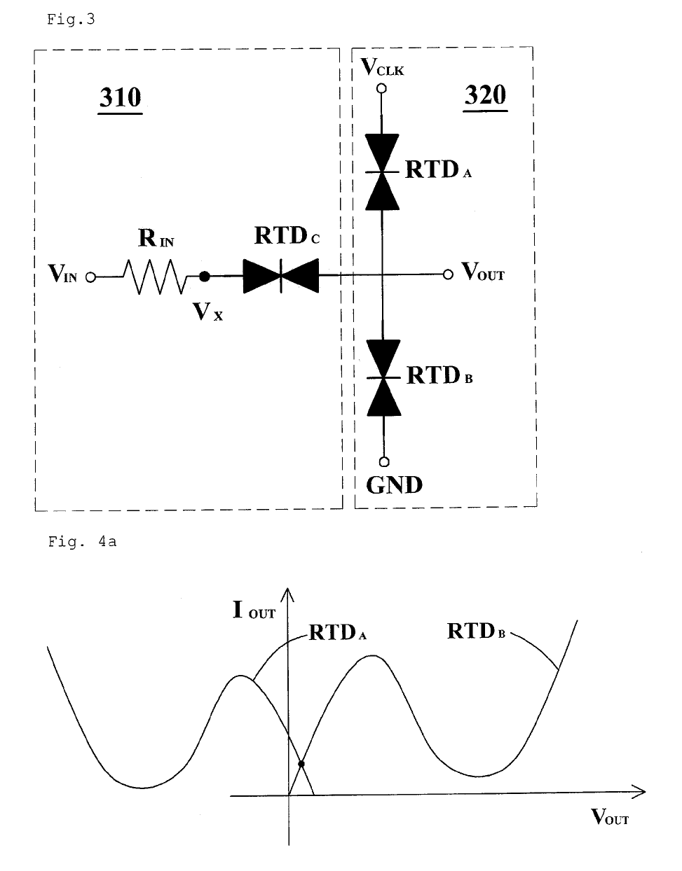

FIG. 3 shows a circuit configuration of a literal gate according to one embodiment of the present invention. By reference to FIG. 3, the literal gate according to the present invention can be roughly divided into an input terminal 310 and an output terminal 320.

The input terminal 310 includes a resistance (R) and an RTD which are connected in series with each other and determines an input value to be inputted to the output terminal 320. That is, an input voltage (V_{IN}) node is connected to one side of an input resistance (R_{IN}), and the other side of the input resistance (R_{IN}) is connected with one side of RTD_{C} in series. The thus-configured input terminal 310 outputs an output value through the other side of the RTD_{C}, which is connected to an output voltage (V_{OUT}) node of the output terminal 320, and at this time, the output value is used as an input value for the output terminal 320.

The output terminal 320, in which a clock signal (V_{CLK}) is used as a control signal, is made to receive an input value from the input terminal 310 and determine an output value (V_{OUT}) of the literal gate according to the received input value. The output terminal 320 comprises at least two RTDs which are connected in series. In the output terminal 320, a clock signal (V_{CLK}) node is connected to one side of RTD_{A} and the other side of RTD_{A}, the other side of RTD_{C} and one side of RTD_{B} are connected to an output voltage (V_{OUT}) node. And the other side of RTD_{B} is connected to a ground (GND). Also, the output terminal 320 is configured to have the V_{OUT} node between RTD_{A} and RTD_{B} which are connected in series.

Here, each of RTD_{A}, RTD_{B}, and RTD_{C} can comprise plural RTDs. Moreover, it is preferable that the plural RTDs are connected in series to one another.

On the other hand, it is preferable to design a circuit in which the peak current (I_{AP}) of RTD_{A} is smaller than the peak current (I_{BP}) of RTD_{B}, in order to utilize the characteristics of RTD elements.

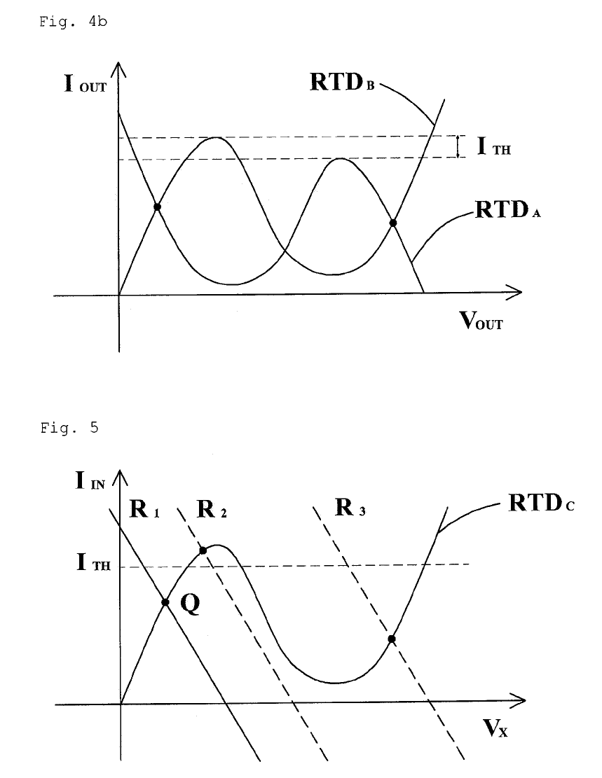

FIGS. 4a and 4b are graphs showing output characteristics of an output terminal according to the present invention.

FIG. 4a is the I-V characteristic graph of the output terminal when the clock signal (V_{CLK}) is in a low state and FIG. 4b is the I-V characteristic graph of the output terminal when the clock signal (V_{CLK}) is in a high state.

By reference to the FIGS. 4a and 4b, when the clock signal (V_{CLK}) is in a low state, the characteristic graphs of RTD_{A} and RTD_{B} make just one stable point, where the characteristic graph of RTD_{A} crosses that of RTD_{B}. And when the clock signal (V_{CLK}) is in a high state, two stable points are made by the characteristic graphs of RTD_{A} and RTD_{B}.

When the clock signal (V_{CLK}) is in a low state, the stable point occurs in the PDR1 areas of the two RTDs, and in this case, the two RTD elements operate in their PDR1 areas and produce an output value (V_{OUT}) of the literal gate in a low state, irrespective of the input value.

When the clock signal (V_{CLK}) is in a high state, the stable points occur in the respective PDR2 areas of the RTDs. In this case, the RTD element having the lower peak current between the two RTDs operates in the PDR2 area. That is, an output value (V_{OUT}) of the literal gate is determined to be in the PDR2 area of the RTD element having the lower peak current.

In the meantime, a difference between the peak current (I_{AP}) of RTD_{A} and the peak current (I_{BP}) of RTD_{B} is expressed as I_{TH}.

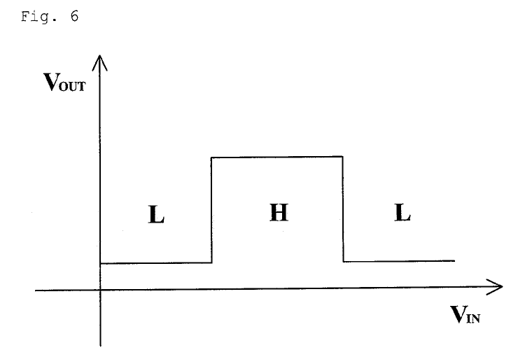

FIG. 5 shows an output characteristic graph of an input terminal according to the present invention and FIG. 6 is a graph showing output values of the literal gate according to the present invention.

By reference to FIGS. 5 and 6, an output of the input terminal 310 in accordance with the present invention is determined by an input resistance (R_{IN}) and RTD_{C}. That is, input current of the output terminal 320 is determined at a Q point where the characteristic graph of the input resistance (R_{IN}) and the characteristic graph of RTD_{C} meet.

The characteristic graph of the input resistance (R_{IN}) moves from R1 in the direction to R3 as the value of the input voltage (V_{IN}) increases. This is because the output value at the V_{X} node is enlarged as the value of the input voltage (V_{IN}) is enlarged.

Here, the input current (I_{IN}) is made to be a value smaller than I_{TH}, if the input resistance (R_{IN}) is R1 And the input current (I_{IN}) is larger than I_{TH}, in the case of R2, and it is smaller than I_{TH} again, in the case of R3. The input current (I_{IN}) determined in this way becomes the value of input current of output terminal 320.

In the meantime, the current to be applied to the output voltage (V_{OUT}) node of the output terminal 320 is determined by the sum of the input current (I_{IN}) and the current (I_{A}) of the RTD_{A}.

If the input current (I_{IN})<I_{TH}, the peak current (I_{BP}) of RTD_{B} is determined to be larger than the peak current (I_{AP}) of RTD_{A}. In this case, the output value (V_{OUT}) of the literal gate is determined at a stable point located in the PDR2 area of RTD_{A} having comparatively low peak current, i.e., at the stable point having the value of output (V_{OUT}) in the comparatively low state between two stable points. In other words, the output value (V_{OUT}) of the literal gate is determined by the output value (V_{OUT}) in the comparatively low state between two possible output values (V_{OUT}).

If the input current (I_{IN})>I_{TH}, the peak current (I_{BP}) of RTD_{B} is determined to be smaller than the peak current (I_{AP}) of RTD_{A}. In that case, the output value (V_{OUT}) of the literal gate is determined at a stable point located in the PDR2 area of RTD_{B} having comparatively low peak current, and the stable point has the comparatively high output value (V_{OUT}) between the two stable points. In other words, the output value (V_{OUT}) of the literal gate is determined by the output value (V_{OUT}) in the comparatively high state between two possible output values (V_{OUT}).

Therefore, an output value (V_{OUT}) of the literal gate according to the present invention is in a high state, only in a particular input area, as shown FIG. 6.

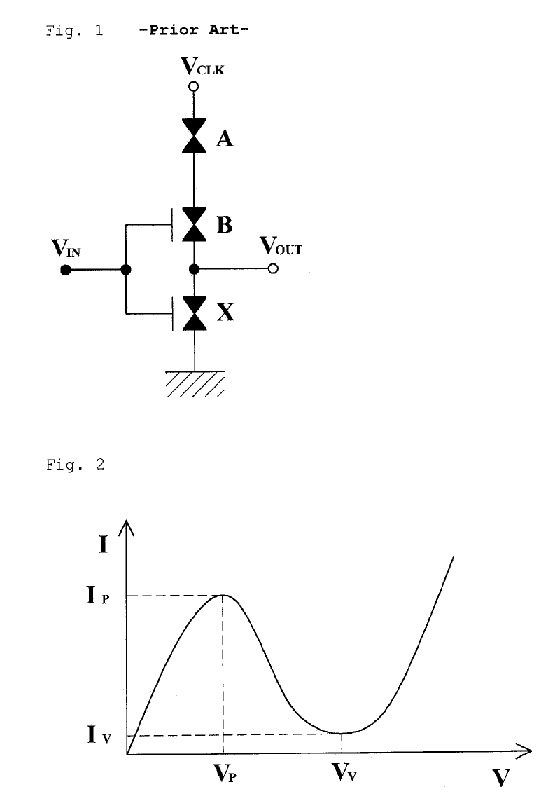

The literal gate in accordance with one embodiment of the present invention is implemented of three RTD elements, which are active elements, and one resistance, which is a passive element. And it can obtain output characteristics of a literal gate even with two fewer active elements than the conventional literal gate having active elements of two transistors and three RTDs, as shown in FIG. 1.

The present invention has an advantage in that it can provide a literal gate using resonant tunneling diodes, utmost utilizing the input-output characteristics of an RTD.

And the present invention has another advantage of providing a literal gate using resonant tunneling diodes having fewer active elements than a conventional literal gate.

And the present invention has another advantage of providing a literal gate using resonant tunneling diodes only, thus capable of miniaturizing the size of a circuit.

And the present invention has advantages of reducing the number of elements required for a literal gate, simplifying the fabricating process and lowering manufacturing costs.

And also, the present invention has another advantage of providing a literal gate using fewer active elements of only one kind, thus improving a fabrication yield, compared to conventional literal gates.

What is claimed is:

1. A literal gate determining an output value according to an input value of an output terminal which is determined by an output value from an input terminal,
the literal gate using resonant tunneling diodes, wherein the input terminal includes a resistance and a resonant tunneling diode (RTD) which are connected in series, to determine the input value.

2. The literal gate as recited in claim 1, wherein the output terminal includes plural resonant tunneling diodes (RTDs) to determine the output value, with using a clock signal as a control signal.

3. The literal gate as recited in claim 2, wherein the output terminal includes plural resonant tunneling diodes (RTDs) which are connected in series.
